(19) United States
(12) Patent Application Publication
(10) Pub. No.: US 2014/0242808 A1
(43) Pub. Date: Aug. 28, 2014

(54) SEMICONDUCTOR DEVICE MANUFACTURING METHOD AND SUBSTRATE PROCESSING SYSTEM

(71) Applicants: Koji Akiyama, Nirasaki (JP); Hirokazu Higashijima, Nirasaki (JP); Chihiro Tamura, Nirasaki (JP); Shintaro Aoyama, Nirasaki (JP)

(72) Inventors: Koji Akiyama, Nirasaki (JP); Hirokazu Higashijima, Nirasaki (JP); Chihiro Tamura, Nirasaki (JP); Shintaro Aoyama, Nirasaki (JP)

(73) Assignee: TOKYO ELECTRON LIMITED, Tokyo (JP)

(21) Appl. No.: 14/342,908

(22) PCT Filed: Aug. 24, 2012
(86) PCT No.: PCT/JP2012/071514

§ 371 Date: Mar. 5, 2014

(30) Foreign Application Priority Data
Sep. 7, 2011 (JP) 2011-195246

(51) Int. Cl. H01L 21/02; C23C 16/52; C23C 16/50; C23C 16/56

(52) U.S. Cl. CPC H01L 21/02318; H01L 21/02181; H01L 21/02189; H01L 21/02186; C23C 16/56; C23C 16/52; C23C 16/50
USPC 438/763; 118/58; 118/704; 118/723 R

(57) ABSTRACT

A semiconductor device manufacturing method includes forming a first high-k insulating film on a processing target object; performing a crystallization heat-treatment process on the first high-k insulating film at a temperature equal to or higher than about 650° C. for a time less than about 60 seconds; and forming, on the first high-k insulating film, a second high-k insulating film containing a metal element having an ionic radius smaller than that of a metal element of the first high-k insulating film and having a relative permittivity higher than that of the first high-k insulating film.

### TECHNICAL FIELD

The embodiments described herein pertain generally to a semiconductor device manufacturing method and a substrate processing system.

### BACKGROUND ART

Recently, in order to meet the requirements for high integration and high performance of a MOSFET (Metal Oxide Semiconductor Field Effect Transistor), a high dielectric constant film (high-k film) has been used as a gate insulating film. Among various high-k materials, a hafnium oxide-based material is attracting attention, and it has been attempted to reduce an equivalent oxide thickness (EOT) by improving a dielectric constant of the material such as hafnium oxide (HfO₂).

As a way to increase the dielectric constant of HfO₂, there have been proposed a method of adding a material having high polarizability such as titanium dioxide (TiO₂) to HfO₂, a method of performing a heat treatment on a HfO₂ film at a high temperature (for example, Patent Document 1), and so forth.
Patent Document 1: U.S. Patent Laid-open Publication No. 2005/0136690 A1

### DISCLOSURE OF THE INVENTION

### Problems to be Solved by the Invention

In the former method, however, since such a material as TiO₂ has a narrow band gap, a composite HfO₂-based insulating film also has a narrow band gap, so that a leakage current is increased. Further, in the latter method in Patent Document 1, the high-k material may be crystallized by performing the heat treatment at the high temperature. Since electricity is conducted via the generated grain boundaries, a leakage current may also be increased in this case.

In view of the foregoing problems, example embodiments provide a semiconductor device manufacturing method and a substrate processing system, capable of reducing both an EOT and a leakage current.

### Means for Solving the Problems

In one example embodiment, a semiconductor device manufacturing method includes forming a first high-k insulating film on a processing target object; performing a crystallization heat-treatment process on the first high-k insulating film at a temperature equal to or higher than about 650° C. for a time less than about 60 seconds; and forming, on the first high-k insulating film, a second high-k insulating film containing a metal element having an ionic radius smaller than that of a metal element of the first high-k insulating film and having a relative permittivity higher than that of the first high-k insulating film.

### Effect of the Invention

In accordance with the example embodiments, it is possible to provide a semiconductor device manufacturing method and a substrate processing system, capable of reducing both an EOT and a leakage current.

### BRIEF DESCRIPTION OF THE DRAWINGS

FIG. 1 is a flow chart for describing a semiconductor device manufacturing method in accordance with an example embodiment.

FIG. 2 is a flowchart for describing a semiconductor device manufacturing method in accordance with another example embodiment.

FIG. 3 is a schematic diagram illustrating a configuration example of a substrate processing system configured to perform a semiconductor device manufacturing method in accordance with the example embodiment.

FIG. 4 is a schematic diagram illustrating a configuration example of a film forming apparatus in accordance with the example embodiment.

FIG. 5 is a schematic diagram illustrating a configuration example of a plasma processing apparatus in accordance with the example embodiment.

FIG. 6 is a schematic diagram illustrating a configuration example of a crystallizing apparatus in accordance with the example embodiment.

FIG. 7 is a table showing an effect of, e.g., a spike annealing process performed based on EOT values and leakage current values of semiconductor devices obtained in an experimental example and comparative examples.

FIG. 8A is a chart showing a concentration distribution of each element in a depth direction of the semiconductor device obtained in the experimental example.

FIG. 8B is a chart showing a concentration distribution of each element in a depth direction of the semiconductor device obtained in the comparative example.

FIG. 9 provides an X-ray diffraction (XRD) analysis result of an example semiconductor device in accordance with the example embodiment.

FIG. 10 is a table showing an effect of a plasma process performed based on EOT values and leakage current values of semiconductor devices obtained in experimental examples and comparative examples.

FIG. 11 is a table showing an effect of forming a WO₃ film as a second high-k insulating film based on EOT values and leakage current values of semiconductor devices obtained in experimental examples and comparative examples.

### DETAILED DESCRIPTION

In the following, example embodiments will be described, and reference is made to the accompanying drawings, which form a part of the description.

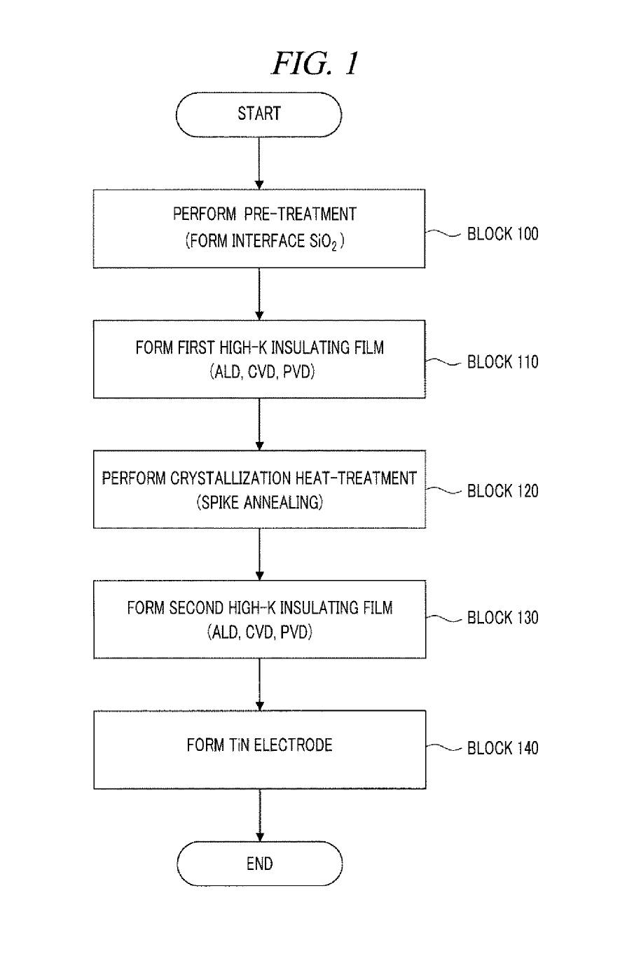

First, referring to FIG. 1, a method of processing a silicon wafer will be described as an example of a semiconductor device manufacturing method in accordance with an example embodiment. Here, although the description will be provided for an example case of forming a gate insulating film by processing the silicon wafer, the example embodiment may not be limited thereto. For example, the semiconductor device manufacturing method in accordance with the example embodiment may also be applicable to a method of forming a capacitive insulating film (capacitor capacitive film) of a capacitor.

FIG. 1 is a flowchart for describing the semiconductor device manufacturing method in accordance with the example embodiment.

First, at block 100, a surface of a silicon wafer is cleaned by, e.g., dilute hydrofluoric acid. If necessary, a pre-treatment of forming an interface layer made of SiO₂ may be performed. The interface layer made of SiO₂ may be formed by cleaning the silicon wafer with hydrochloric acid/hydrogen peroxide (HCl/H₂O₂). Typically, the interface layer of SiO₂ may be formed in a thickness of, e.g., about 0.3 nm.

Thereafter, at block 110, a first high-k insulating film is formed. Desirably, a hafnium oxide (HfO₂) film, a zirconium oxide (ZrO₂) film, a zirconium hafnium oxide (HfZrOₓ) film or a stacked film of combinations thereof (e.g., a stacked film of ZrO₂/HfO₂) may be used as the first high-k insulating film. In the present example embodiment, a hafnium oxide film is used as the first high-k insulating film and formed in a thickness of, e.g., about 2.5 nm.

The first high-k insulating film may be formed by ALD (Atomic Layer Deposition), CVD (Chemical Vapor Deposition), PVD (Physical Layer Deposition), or the like. Among these methods, since the ALD method can form a film at a low temperature and has a good step coverage, it is desirable to use the ALD method.

As a source material (precursor) to be used in forming a first high-k insulating film by CVD or ALD, an example of a precursor for use in forming a HfO₂ film will be described. However, the precursor may not be particularly limited thereto. As another example of the precursor for use in forming the HfO₂ film, an amide-based organic hafnium compound such as TDEAH (tetrakis (diethylamino) hafnium) or TEMAH (tetrakis (ethylmethylamino) hafnium), an alkoxide-based organic hafnium compound such as HTB (hafnium tetra-tertiary butoxide), or the like may be used. As an oxidizing agent, an O₃ gas, an O₂ gas, a H₂O gas, a NO₂ gas, a NO gas, a N₂O gas, or the like may be used. Here, it may be also possible to enhance reactivity by exciting the oxidizing agent into plasma.

In case of forming a HfO₂ film by ALD, the HfO₂ film is formed by alternately repeating a sequence of adsorbing a Hf source material thinly and a sequence of supplying the oxidizing agent. Meanwhile, in case of forming a HfO₂ film by CVD, the Hf source material and the oxidizing agent are simultaneously supplied while the silicon wafer is being heated. When forming the HfO₂ film by ALD, a film forming temperature may be typically set to be in the range from, e.g., about 150° C. about 350° C. Meanwhile, when forming the HfO₂ film by CVD, the film forming temperature may be typically set to be in the range from, e.g., about 350° C. to about 600° C.

After the first high-k insulating film is formed, at block 120, a crystallization heat-treatment is performed to crystallize the first high-k insulating film.

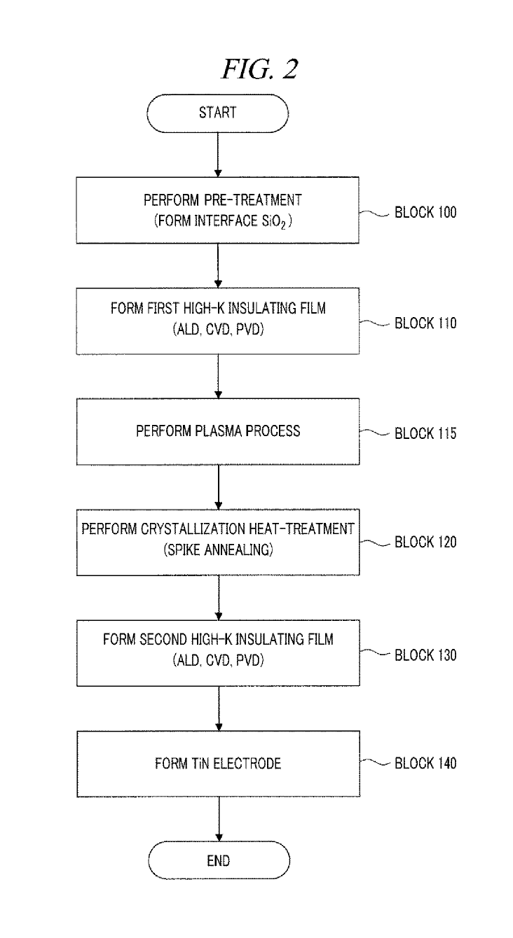

Prior to block 120, a process of performing a plasma process on the first high-k insulating film may be additionally performed. FIG. 2 is a flowchart for describing a semiconductor device manufacturing method in accordance with another example embodiment. This example embodiment is the same as the first example embodiment except that block 115 for performing a plasma process is added between block 110 and block 120.

By performing the plasma process, it is possible to remove a microstructure remaining after forming the HfO₂ film. Accordingly, a cubic crystal system or a tetragonal crystal system having a high relative permittivity to be described layer can be easily precipitated in the crystallization heat-treatment at block 120.

At a low temperature, a main crystal system of the HfO₂ film formed as the first high-k is a monoclinic crystal system, which is a stable crystal system, and, thus, its relative permittivity (∈) is about 16. Meanwhile, at a low temperature, the HfO₂ has a cubic crystal system (having a relative permittivity (∈) of about 29) or a tetragonal crystal system (having a relative permittivity (∈) of about 70), which is a semi-stable crystal system. Thus, by performing the heat treatment (spike annealing) on the HfO₂ film for a short period of time, it is possible to precipitate the cubic crystal system or the tetragonal crystal system having a high dielectric constant on the HfO₂ film. By rapidly cooling the HfO₂ film on which the cubic crystal system or the tetragonal crystal system is precipitated, it is possible to obtain a HfO₂ film having the cubic crystal system or the tetragonal crystal system.

Typically, grain boundaries of a HfO₂ film and a TiO₂ film are formed by crystallization. Since their diffusion coefficients increase through the crystallization, inter-diffusion therebetween may easily occur. Especially, the inter-diffusion is highly likely to occur at a high temperature. If crystallization heat-treatment is performed after the HfO₂ film and the TiO₂ film are formed, the HfO₂ film and the TiO₂ film may be diffused into each other, so that the HfO₂ film may be changed into a HfTiO film. At this time, a band offset of the HfO film may be decreased to a band offset value of the TiO₂ film and a leakage current may be increased. Since, however the crystallization heat-treatment of block 120 is performed before a second high-k insulating film is formed (block 130), the inter-diffusion between the first high-k film and the second high-k film may be suppressed.

Spike annealing using a RTP (Rapid Thermal Process) device, such as lamp heating, may be performed as the crystallization heat-treatment. The crystallization heat-treatment needs to be performed at a temperature (typically, equal to or higher than about 650° C.) at which a high-k insulating film is crystallized. In the present example embodiment, the crystallization heat-treatment is performed at, e.g., about 700° C. (under a depressurized N₂ atmosphere). Further, a heat applying time for the spike annealing may be set to be less than, e.g., about 60 seconds, desirably, and, more desirably, in the range from, e.g., about 0.1 sec to about 10 sec. If the heat applying time for the spike annealing exceeds, e.g., about 60 seconds, a monoclinic crystal system, which is a stable crystal system of the HfO₂ film, may be precipitated.

Upon the completion of the crystallization heat-treatment, at block 130, the second high-k insulating film is formed. It may be desirable to use, as the second high-k insulating film, a material having a dielectric constant (a higher relative permittivity) higher than that of the first high-k insulating film. Further, it may be also desirable to use a material containing a metal element having an ionic radius smaller than an ionic radius of a metal element of the first high-k insulating film (e.g., Hf in the case of HfO₂). This is because that voids in the first high-k insulating film (HfO₂) can be decreased and a molecular volume is reduced by introducing the material containing the metal element having the smaller ionic radius. Thus, electrical characteristics of the first high-k insulating film may be improved.

As a specific example, a titanium dioxide (TiO₂) film, tungsten trioxide (WO₃) film or a titanate film (e.g., represented by TiₓMe_{y}O_{z}, and Me denotes Hf, Zr, Ce, Nb, Ta, Si, Al, Sr, or the like) may be used as the second high-k insulating film. In the present example embodiment, although a TiO₂ film or a WO₃ film are used as the second high-k insulating film, the second high-k insulating film may not be limited thereto.

The second high-k insulating film may be formed by ALD, CVD, PVD, or the like. In order to suppress inter-diffusion between the first and second high-k insulating films when forming the second high-k insulating film, it may be desirable to form the second high-k insulating film at a temperature as low as possible. Thus, it may be desirable to employ a low-temperature PVD method or an ALD method that enables film formation at a low temperature.

Further, a precursor for use in forming the second high-k insulating film by CVD or ALD may be appropriately selected from known materials. By way of non-limiting example, TiCl₄, Ti(O-iPr)₄ may be used as a CVD or ALD source material (precursor) for Ti. However, the precursor may not be limited thereto, and another known precursor may be used instead. Further, the aforementioned oxidizing agent used in forming the HfO₂ film may also be used.

Although varied depending on the material of the second high-k insulating film, a thickness of the second high-k insulating film may be set to be equal to or less than, e.g., about 5 nm. To elaborate, when using TiO₂ as the second high-k insulating film, the thickness of the second high-k insulating film may be equal to or less than, e.g., about 5 nm, desirably. Likewise, when using WO₃ as the second high-k film, the thickness of the second high-k film may be se to be equal to or less than, e.g., about 5 nm, and, more desirably, be in the range from, e.g., about 0.2 nm to about 0.5 nm. If the thickness of the second high-k insulating film exceeds about 5 nm, a short channel characteristic may be degraded because of FIBL (Fringing Induced Barrier Lowering).

After the second high-k insulating film is formed, at block 140, a gate electrode of, e.g., TiN is formed by, e.g., PVD, and a semiconductor device is manufactured. The manufactured semiconductor device is sintered at a low temperature of, typically, about 400° C. and unpaired electrons between the insulating film and the silicon are electrically deactivated.

(Substrate Processing System for the Present Example Embodiment)

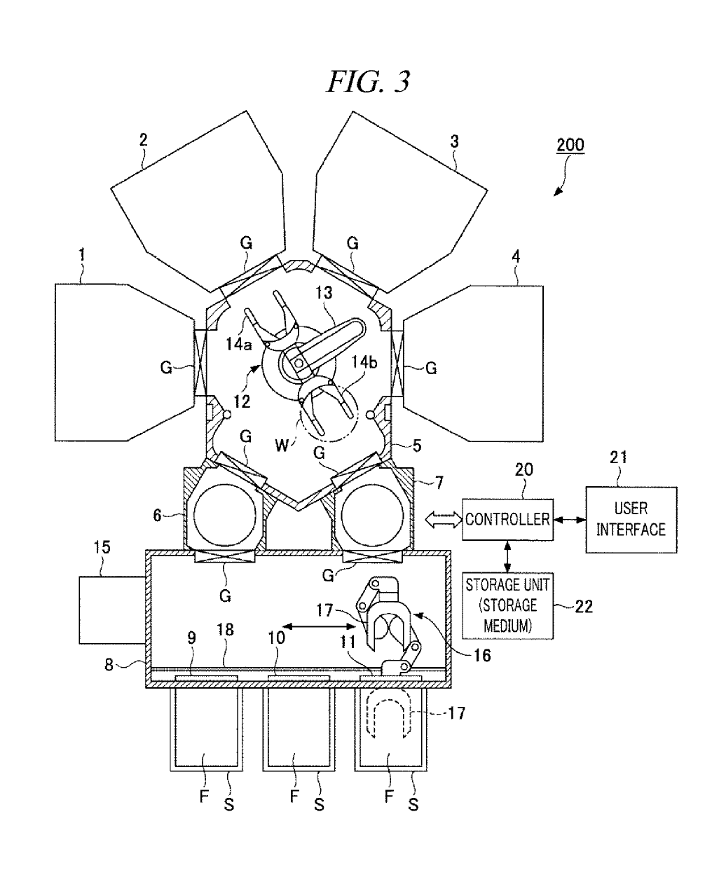

Now, a substrate processing system for performing the semiconductor device manufacturing method in accordance with the example embodiment will be described with reference to FIG. 3.

FIG. 3 is a schematic diagram illustrating a configuration example of a substrate processing system 200 configured to perform the semiconductor device manufacturing method in accordance with the example embodiment. The substrate processing system 200 is configured to perform processes of block 110 to block 130 on a silicon wafer on which the pre-treatment of block 100 in FIG. 1 is previously performed.

As depicted in FIG. 3, the substrate processing system 200 includes two film forming apparatuses 1 and 2 configured to form a first high-k insulating film and a second high-k insulating film, respectively; and a crystallizing apparatus 4 configured to perform crystallization heat-treatment on the first high-k insulating film in block 120. Desirably, the substrate processing system 200 further includes a plasma processing apparatus 3 configured to perform a plasma process on the first high-k insulating film in block 115.

The film forming apparatuses 1 and 2, the crystallizing apparatus 4 and the plasma processing apparatus 3 are arranged to correspond to four sides of a hexagonal wafer transfer chamber 5, respectively. Load lock chambers 6 and 7 are installed at the other two sides of the wafer transfer chamber 5. A wafer loading/unloading chamber 8 is provided at the opposite sides of the load lock chambers 6 and 7 with respect to the wafer transfer chamber 5. Ports 9, 10 and 11 configured to mount thereon three FOUPs F accommodating therein silicon wafers W are provided at the opposite side of the wafer loading/unloading chamber 8 with respect to the load lock chambers 6 and 7.

The film forming apparatuses 1 and 2, the crystallizing apparatus 4, the plasma processing apparatus 3 and the load lock chambers 6 and 7 are connected to the respective sides of the hexagonal wafer transfer chamber 5 via gate valves G. By opening the gate valves G, they are allowed to communicate with the wafer transfer chamber 5, and by closing the gate valves G, they are isolated from the wafer transfer chamber 5. Further, the load lock chambers 6 and 7 are also connected to the wafer loading/unloading chamber 8 by the gate valves G. By opening the gate valves G, the load lock chambers 6 and 7 are allowed to communicate with the wafer loading/unloading chamber 8, and by closing the gate valves G, the load lock chambers 6 and 7 are isolated from the wafer loading/unloading chamber 8

Provided in the wafer transfer chamber 5 is a wafer transfer device 12 configured to transfer a wafer W into/from the film forming apparatuses 1 and 2, the crystallizing apparatus 4, the plasma processing apparatus 3 and the load lock chambers 6 and 7. The wafer transfer device 12 is provided at a substantially central portion of the wafer transfer chamber 5. The wafer transfer device 12 includes a rotating/extending/retracting portion 13 that is rotatable, extensible and contractible. Two blades 14a and 14b configured to hold thereon wafers W are provided at a leading end of the rotating/extending/retracting portion 13. The blades 14a and 14 are fastened to the rotating/extending/retracting portion 13 to face to opposite directions each other. The inside of the wafer transfer chamber 5 is maintained at a certain vacuum degree.

Further, a HEPA filter (not shown) is provided at a ceiling portion of the wafer loading/unloading chamber 8. Clean air in which organic substances or particles are removed by being passed through the HEPA filter is supplied downward into the wafer loading/unloading chamber 8. Accordingly, loading/unloading of the wafer W is performed in a clean air atmosphere of an atmospheric pressure. A shutter (not shown) is provided at each of the three ports 9, 10 and 11 of the wafer loading/unloading chamber 8. A FOUP F accommodating wafers W therein or an empty FOUP F is directly mounted on each of the ports 9, 10 and 11. After the FOUP F is mounted on corresponding one of the ports 9, 10 and 11, the shutter is opened, and the FOUP F is allowed to communicate with the wafer loading/unloading chamber 8. Further, provided at a lateral side of the wafer loading/unloading chamber 8 is an alignment chamber 15 in which alignment of wafers W is performed.

A wafer transfer device 16 configured to load and unload wafers W into/from the FOUPs F and into/from the load lock chambers 6 and 7 is provided in the wafer loading/unloading chamber 8. The wafer transfer device 16 has two multi-joint arms and is configured to be movable on a rail 18 in an arrangement direction of the FOUPs F. In FIG. 3, the wafers W are transferred while held on hands 17 provided at leading ends of the multi-joint arms of the wafer transfer device 16. Further, in FIG. 3, one hand 17 is shown to be located in the wafer transfer chamber 8, while the other hand 17 is inserted in the FOUP F.

Constituent components of the substrate processing system 200 (e.g., the film forming apparatuses 1 and 2, the crystallizing apparatus 4, the plasma processing apparatus 3, the wafer transfer devices 12 and 16) are connected to and controlled by a controller 20 having a computer. The controller 20 is connected to a user interface 21 including a keyboard through which an operator inputs commands to manage the substrate processing system, a display which visually displays an operational status of the substrate processing system, and so forth.

The controller 20 is also connected to a storage unit 22 which stores therein control programs for implementing various processes performed in the substrate processing system under the control of the controller 20, programs (i.e., processing recipes) for implementing a process in each component according to processing conditions, etc. The processing recipes are stored on a storage medium within the storage unit 22. The storage medium may be a hard disk or a portable device such as a CDROM, a DVD or a flash memory. Alternatively, the processing recipes may be appropriately transmitted from another apparatus through, e.g., a dedicated line.

In response to an instruction from, e.g., the user interface 21, a necessary recipe is read out from the storage unit 22 and executed by the controller 20, so that a desired process is performed in the substrate processing system 200. The controller 20 may be configured to control each component directly, or individual controllers may be provided in the respective components and the controller 20 may control the respective components via the individual controllers.

In the substrate processing system 20 in accordance with the example embodiment, a FOUP F accommodating therein wafers W, on which the pre-treatment is previously performed, is loaded. Then, a single wafer W is taken out of the FOUP F and loaded into the alignment chamber 15 by the wafer transfer device 16 within the wafer loading/unloading chamber 8 which is maintained in the clean air atmosphere of the atmospheric pressure. After the wafer W is aligned in the alignment chamber 15, the wafer W is loaded into either one of the load lock chambers 6 and 7, and the inside of the load lock chamber is evacuated. Then, the wafer W is taken out of the load lock chamber and loaded into the film forming apparatus 1 by the wafer transfer device 12 within the wafer transfer chamber 5, and a film forming process of block 110 is performed. After a first high-k film insulating film is formed, the wafer W is taken out of the film forming apparatus 1 by the wafer transfer device 12 and, desirably, loaded into the plasma processing apparatus 3 and a plasma process of block 115 is performed on the first high-k insulating film. Thereafter, the wafer W is taken out of the plasma processing apparatus 3 by the wafer transfer device 12 and loaded into the crystallizing apparatus 4, and a crystallizing process of block 120 is performed. Thereafter, the wafer W is taken out of the crystallizing apparatus 4 by the wafer transfer device 12 and loaded into the film forming apparatus 2 and then a film forming process of block 130 is performed. After the film forming process of block 130, the wafer W is loaded into either one of the load lock chambers 6 and 7 by the wafer transfer device 12, and the inside of the load lock chamber is returned back into an atmospheric pressure. Thereafter, the wafer W is taken out of the load lock chamber by the wafer transfer device 16 within the wafer loading/unloading chamber 8 and then is accommodated in any one of FOUPs F. These operations are performed for a single lot of wafers W, and a single set of processes are completed.

(Configuration Example of Film Forming Apparatuses 1 and 2)

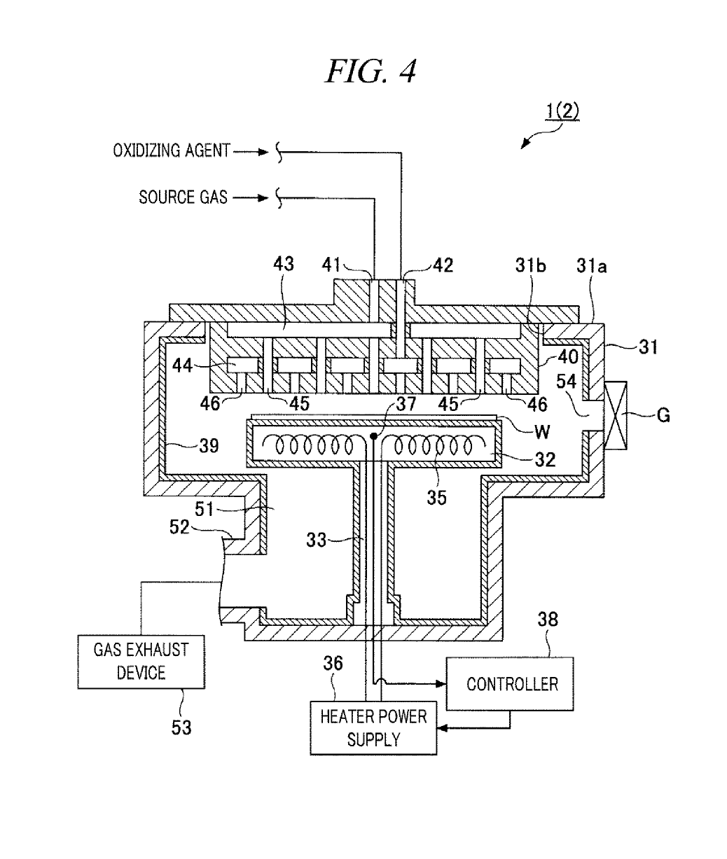

Now, a configuration of the film forming apparatuses 1 and 2 configured to perform the processes of block 110 and block 130, respectively, will be explained with reference to FIG. 4. FIG. 4 is a schematic diagram illustrating a configuration example of the film forming apparatus 1 (or 2) in accordance with the example embodiment. Here, although the film forming apparatus 1 (2) is configured to perform the film forming process by, for example, ALD or CVD as a desirable film forming method of forming a first (second) high-k insulating film, the configuration of the film forming apparatus 1 (2) may not be limited thereto and may have a configuration (not shown) for performing film formation by PVD.

The film forming apparatus 1 includes a hermetically sealed chamber 31 having a substantially cylindrical shape. A susceptor 32 configured to mount a wafer W as a processing target object thereon horizontally is provided in the chamber 31. A cylindrical supporting member 33 is provided under a central portion of the susceptor 32 and the susceptor 32 is supported on the supporting member 33. The susceptor 32 is made of ceramics such as, but not limited to, AlN.

Further, a heater 35 is embedded in the susceptor 32, and a heater power supply 36 is connected to the heater 35. A thermocouple 37 is provided within the susceptor 32 near a top surface thereof, and a signal from the thermocouple 37 is sent to a controller 38. The controller 38 sends an instruction to the heater power supply 36 according to the signal from the thermocouple 37 and controls heating of the heater 35. As a result, the wafer W can be controlled to have a preset temperature.

A quartz liner 39 is provided on an inner wall of the chamber 31 and peripheries of the susceptor 32 and the supporting member 33 to suppress adhesion of deposits thereto. A purge gas (shield gas) is flown between the quartz liner 39 and the inner wall of the chamber 31. Accordingly, it is possible to suppress deposits from adhering to the inner wall of the chamber, so that contamination can be suppressed. Further, since the quartz liner 39 is detachably provided, it may be possible to conduct maintenance of the inside of the chamber 31 efficiently.

An annular hole 31b is formed in a ceiling wall 31a of the chamber 31, and a shower head 40 protruding to the inside of the chamber 31 is fitted in the hole 31b. The shower head 40 is configured to discharge the aforementioned source gas for film formation into the chamber 31. A first inlet path 41 for introducing the source gas and a second inlet path 42 for introducing an oxidizing agent are connected an upper portion of the shower head 40.

Spaces 43 and 44 are formed within the shower head 40 in two levels. The first inlet path 41 is connected to the upper space 43, and a first gas discharge path 45 communicating with this space 43 is extended to a bottom surface of the shower head 40. The second inlet path 42 is connected to the lower space 44, and a second gas discharge path 46 communicating with this space 44 is also extended to the bottom surface of the shower head 40. That is, the shower head 40 has a post-mix type configuration that allows the source gas and the oxidizing agent to be uniformly diffused in the spaces 43 and 44, respectively, without mixed with each other, and then, discharged independently through the gas discharge paths 45 and 46.

Further, the susceptor 32 is configured to be movable up and down by a non-illustrated elevating device. Accordingly, a process gap is adjusted to minimize a space exposed to the source gas.

A gas exhaust chamber 51 protruding downward is provided in a bottom wall of the chamber 31. A gas exhaust line 52 is connected to a lateral side of the gas exhaust chamber 51, and a gas exhaust device 53 is connected to the gas exhaust line 52. It is possible to depressurize the inside of the chamber 31 to a preset vacuum level by the gas exhaust device 53.

A loading/unloading opening 54 through which a wafer W is loaded/unloaded into/from the wafer transfer chamber 5 and a gate valve G for opening and closing the loading/unloading opening 54 are provided at a sidewall of the chamber 31.

When forming the first (second) high-k insulating film by CVD, the aforementioned source gas and the oxidizing agent are concurrently supplied into the shower head 40 through the first inlet path 41 and the second inlet path 42, respectively. Meanwhile, when forming the first (second) high-k insulating film by ALD, the aforementioned source gas and oxidizing agent are supplied alternately. By way of example, the source gas may be supplied through the sequences of force-feeding a liquid source from a source receptacle and vaporizing the liquid source by a vaporizer.

In the film forming apparatus configured as described above, after the wafer W is loaded into the chamber 31, the inside of the chamber 31 is evacuated to be a preset vacuum state. Then, the wafer W is heated to a preset temperature by the heater 35. In this state, in case of CVD, the source gas and the oxidizing agent are concurrently supplied into the shower head 40 through the first inlet path 41 and the second inlet path 42, respectively, and then, introduced into the chamber 31. In case of ALD, the source gas and the oxidizing agent are alternately introduced into the chamber 31.

The source gas and the oxidizing agent react with each other on the heated wafer W, so that a high-k insulating film is formed on the wafer W.

(Configuration Example of Plasma Processing Apparatus 3)

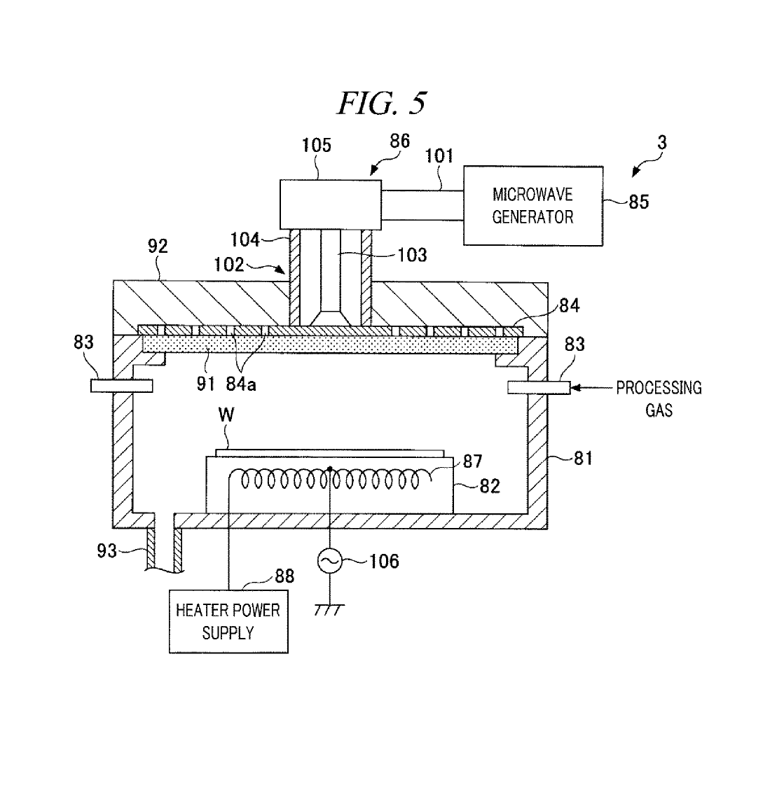

Now, the plasma processing apparatus 3 configured to perform the process of block 115 will be explained with reference to FIG. 5. FIG. 5 is a schematic diagram illustrating a configuration example of the plasma processing apparatus 3 in accordance with the example embodiment.

Here, the plasma processing apparatus is configured as, for example, a microwave plasma processing apparatus of a RLSA (Radial Line Slot Antenna) microwave plasma type. However, the example embodiment may not be limited thereto.

The plasma processing apparatus 3 includes a substantially cylindrical chamber 81; a susceptor 82 provided in the chamber 81; and a gas supplying unit 83 provided in a sidewall of the chamber 81 and configured to introduce a processing gas. Further, the plasma processing apparatus 3 further includes a planar antenna 84 disposed to face a top opening of the chamber 81 and having a multiple number of microwave transmission holes 84a; a microwave generator 85 configured to generate a microwave; a microwave transmitting device 86 configured to introduce the microwave generated by the microwave generator 85 to the planar antenna 84.

A microwave transmitting plate 91 made of a dielectric material is provided under the planar antenna 84, and a shield member 92 is provided on the planar antenna 84. The shield member 92 has a water-cooling structure (not shown). Further, a wavelength shortening member made of a dielectric material may also be provided on a top surface of the planar antenna 84.

The microwave transmitting unit 86 includes a waveguide 101 horizontally extended and configured to introduce a microwave from the microwave generator 85; a coaxial waveguide 102 that is upwardly extended and has an inner conductor 103 and an outer conductor 104; and a mode converter 105 provided between the waveguide 101 and the coaxial waveguide 102. A gas exhaust pipe 93 is provided in a bottom wall of the chamber 81, and the inside of the chamber 81 can be evacuated to a preset vacuum level through the gas exhaust pipe 93 by a non-illustrated gas exhaust device.

Further, a high frequency power supply 106 for ion attraction may be connected to the susceptor 82. A heater 87 is embedded in the susceptor 82, and a heater power supply 88 is connected to the heater 87. Heating of the heater 87 is controlled by a voltage applied from the heater power supply 88, so that the wafer W is controlled to have a preset temperature.

In the plasma processing apparatus 3, the microwave generated by the microwave generator 85 is introduced to the planar antenna 84 in a preset mode via the microwave transmitting device 86, and then, is uniformly supplied into the chamber 81 through the microwave transmission holes 84a of the planar antenna 84 and the microwave transmitting plate 91. The processing gas supplied from the gas supplying unit 83 is ionized or dissociated into plasma, and the first high-k insulating film on the wafer W is plasma-processed by active species (e.g., radicals) in the plasma. The processing gas may be, but not limited to, an O₂ gas, an O₂ gas plus a rare gas (inert gas), a rare gas, and a rare gas plus a N₂ gas.

(Configuration Example of Crystallizing Apparatus 4)

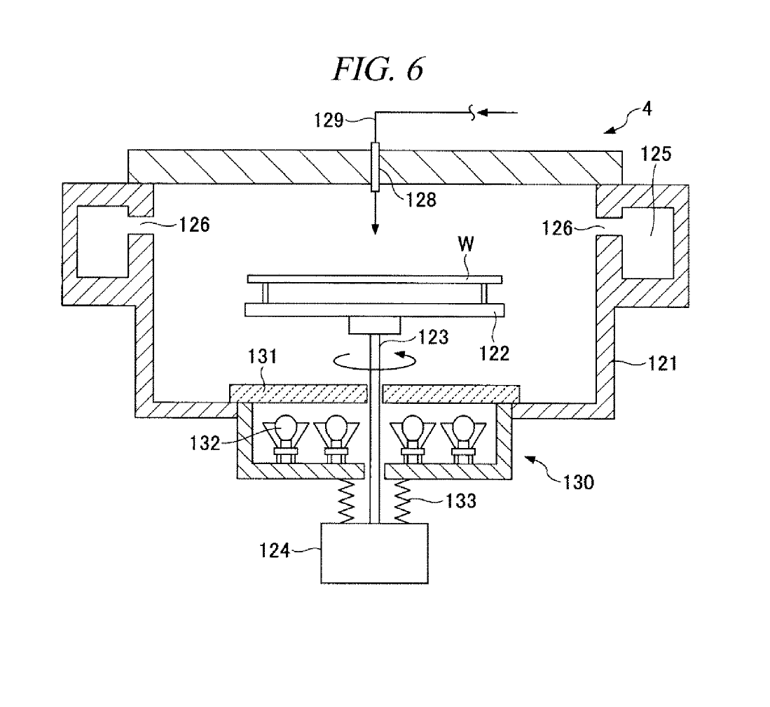

Now, the crystallizing apparatus 4 configured to perform the process of block 120 will be discussed with reference to FIG. 6. FIG. 6 is a schematic diagram illustrating a configuration example of the crystallizing apparatus 4 in accordance with the example embodiment.

The crystallizing apparatus 4 depicted in FIG. 6 is configured as a RTP apparatus using lamp heating and performs spike annealing on the first high-k insulating film. The crystallizing apparatus 4 includes a hermetically sealed chamber 121 having a substantially cylindrical shape. A supporting member 122 that supports a wafer W to be rotated is provided in the chamber 121. A rotation shaft 123 of the supporting member 122 is extended downward and is rotated by a rotation driving device 124 provided outside the chamber 121. With this configuration, the wafer W is rotated along with the supporting member 122.

An annular gas exhaust path 125 is formed around the chamber 121, and the chamber 121 and the gas exhaust path 125 are connected through gas exhaust holes 126. A non-illustrated gas exhaust device such as a vacuum pump is connected to at least one place of the gas exhaust path 125.

A gas inlet line 128 is inserted in a ceiling wall of the chamber 121 and a gas supply line 129 is connected to the gas inlet line 128. That is, a processing gas is introduced into the chamber 121 through the gas supply line 129 and the gas inlet line 128. A rare gas such as an Ar gas or a N₂ gas may be appropriately used as the processing gas.

A lamp chamber 130 is provided at a bottom portion of the chamber 121, and a light transmitting plate 131 made of a transparent material such as quartz is provided on a top surface of the lamp chamber 130. A multiple number of heating lamps 132 are provided in the lamp chamber to heat the wafer W. Further, a bellows 133 is provided to surround the rotation shaft 123 between a bottom surface of the lamp chamber 130 and the rotation driving device 124.

In the crystallizing apparatus 4, after the wafer W is loaded into the chamber 121, the inside of the chamber 121 is evacuated to be a preset vacuum state. Then, while introducing the processing gas into the chamber 121, the wafer W is rotated along with the supporting member 122 by the rotation driving device 124. Further, a temperature of the wafer W is rapidly increased by the lamps 132 in the lamp chamber 130. If the temperature of the wafer W reaches a preset temperature, the lamps 132 are turned off, and the temperature of the wafer W decreases rapidly. Through this process, crystallization can be performed in a short period of time.

Further, the wafer W need not necessarily be rotated. Further, the lamp chamber 130 may be provided above the wafer W. In such a configuration, it may be possible to provide a cooling device on the rear surface side of the wafer W and to reduce the temperature of the wafer W more rapidly.

### EXAMPLE EMBODIMENTS

Now, examples for investigating effects of the semiconductor device manufacturing method in accordance with the example embodiment will be explained.

### First Example Embodiment

First, at block 100, a surface of a silicon wafer is cleaned by, e.g., dilute hydrofluoric acid. Then, by cleaning the silicon wafer with hydrochloric acid/hydrogen peroxide, an interface layer made of SiO₂ is formed. After the interface layer is formed, at block 110, a HfO₂ film having a thickness of, e.g., about 2.5 nm is formed on the silicon wafer W as a first high-k insulating film by ALD. Then, at block 120, spike annealing is performed at a temperature of, e.g., about 700° C. Further, at block 130, a TiO₂ film having a thickness of, e.g., about 3 nm is formed as a second high-k insulating film by PVD. Thereafter, at block 140, a TiN film having a thickness of, e.g., about 10 nm is formed as a gate electrode by PVD, and heat-treatment is performed at a low temperature of, e.g., about 400° C. for, e.g., about 10 minutes. As a result, a semiconductor device of an experimental example 1 is manufactured.

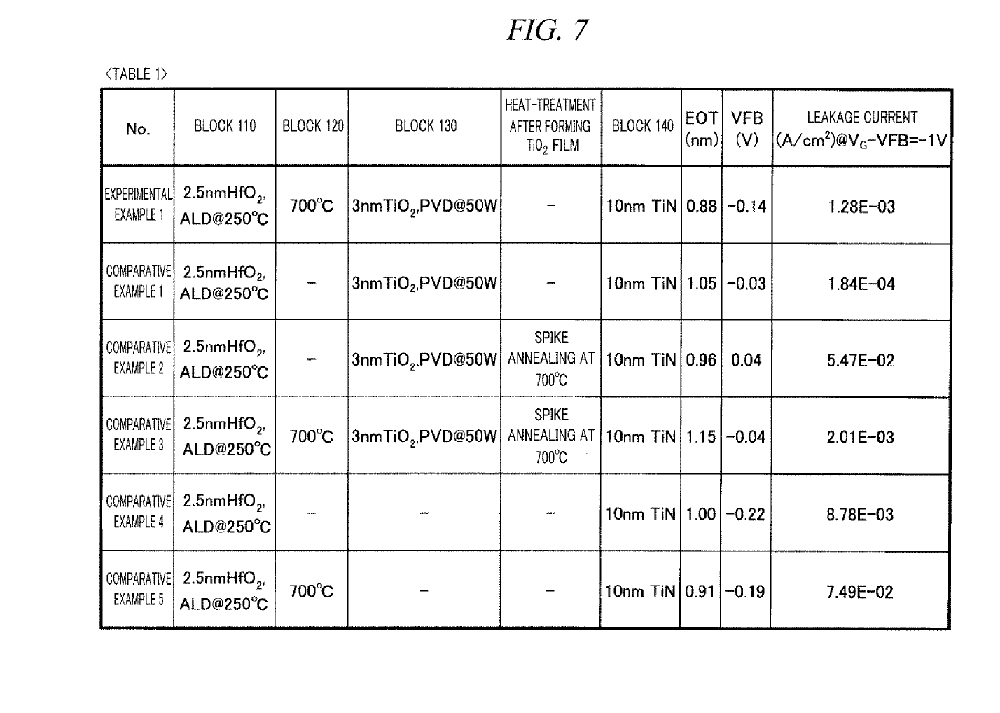

Further, as comparative examples, a case without performing the spike annealing of block 120, a case without forming the second high-k insulating film in block 130 and a case of performing a high-temperature heat-treatment after block 130 are provided. Detailed manufacturing conditions of the experimental example and the comparative examples are shown in Table 1 of FIG. 7.

Table 1 shows EOTs (nm) and leakage currents (A/cm²) of semiconductor devices obtained in the experimental example and the comparative examples. Further, flat band voltages (VFB; V) are also shown in Table 1.

As can be seen from Table 1, the semiconductor device obtained in the experimental example 1 has the smallest EOT. As for the leakage current, although a leakage current in a comparative example 1 is smaller than that in the experimental example 1, an EOT in the comparative example 1 is equal to or larger than about 1 nm. As can be seen from this result, the method of the experimental example 1 is capable of suppressing a leakage current while reducing an EOT (capable of achieving required characteristic values of both of EOT and leakage current).

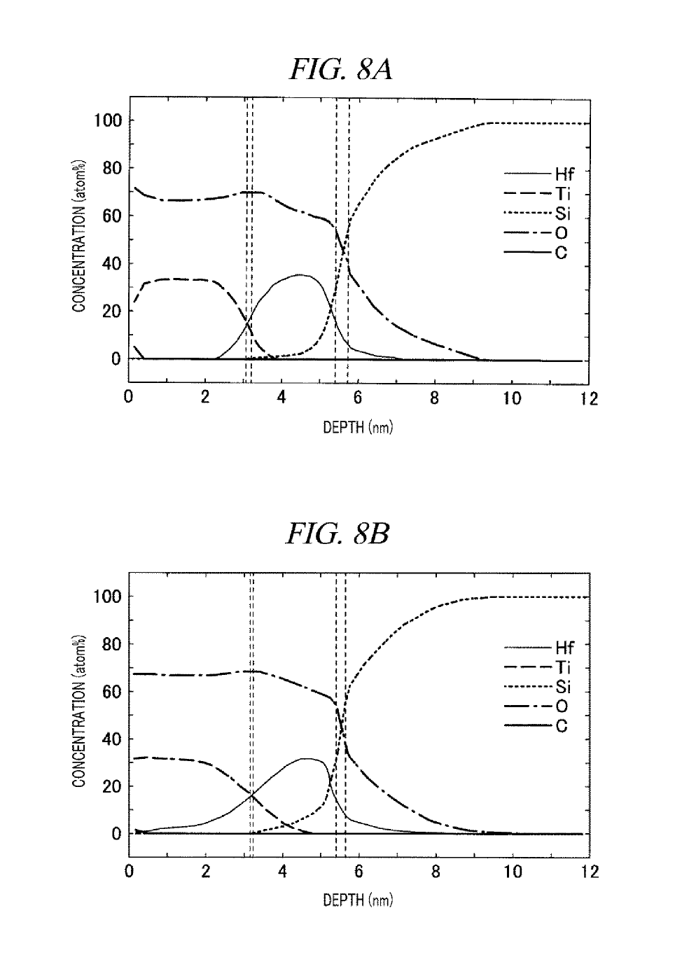

FIG. 8A and FIG. 8B show a concentration distribution of each element in a depth direction of the semiconductor devices obtained in the experimental example 1 (see FIG. 8A) and a comparative example 2 (see FIG. 8B), which is analyzed by high resolution Rutherford backscattering spectrometry (HR-RBS). In each graph, an axial direction of a horizontal axis indicates a vertically downward direction from a top surface of the TiO₂ film, assuming that the top surface of the TiO₂ film is 0 nm when the silicon wafer W is placed on a horizontal plane.

As can be seen from FIG. 8B, in the semiconductor device obtained by the method of the comparative example 2, Hf and Ti are inter-diffused at an interface between the first high-k insulating film (HfO₂ film) and the second high-k insulating film (TiO₂ film). Especially, Hf is found to be diffused deep into the TiO₂, which is one of factors that cause an increase of a leakage current. The increase of the inter-diffusion between Hf and Ti is found to be caused because the crystallization heat-treatment is performed at the high temperature of, e.g., about 700° C. after the HfO₂ film and the TiO₂ film are formed. As a result, grain boundaries are formed, and a diffusion coefficient increases.

Meanwhile, as can be seen from FIG. 8A, as compared to the semiconductor device obtained by the method of the comparative example 2, inter-diffusion of Hf and Ti is suppressed in the semiconductor device obtained by the method of the experimental example 1. This is found to be because the crystallization heat-treatment is performed after the HfO₂ film is formed, the TiO₂ film is formed after the crystallization heat treatment, and, high-temperature heat-treatment is not performed after the TiO₂ film is formed.

### Second Example Embodiment

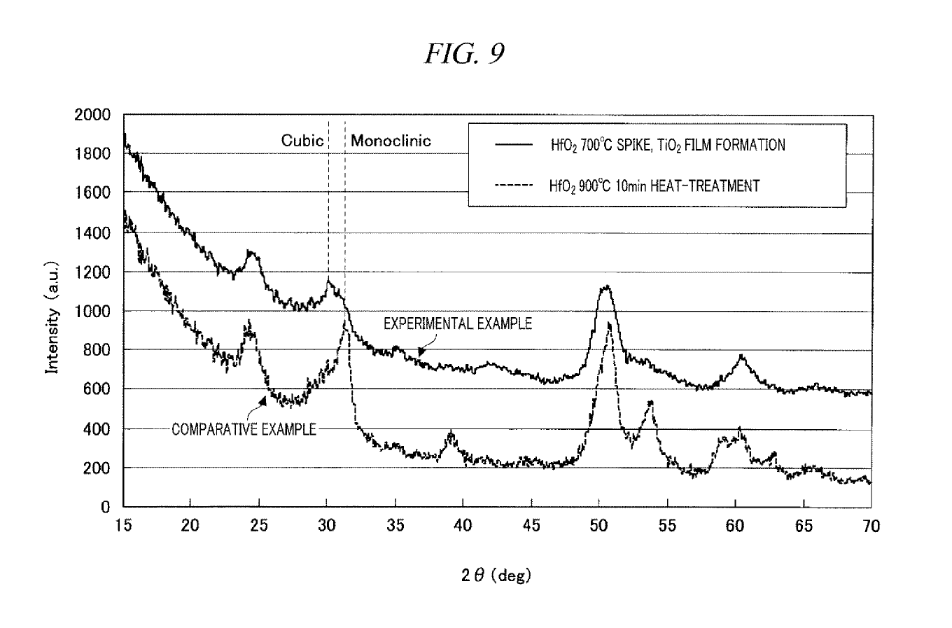

Now, an experiment for investigating an effect of the spike annealing (short-time heat-treatment (block 120)) in the semiconductor device manufacturing method in accordance with the example embodiment will be described with reference to FIG. 9.

FIG. 9 shows an X-ray diffraction (XRD) analysis result of a film formed by the semiconductor device manufacturing method in accordance with the example embodiment.

First, at block 100, a surface of a silicon wafer is cleaned by, e.g., dilute hydrofluoric acid. Then, by cleaning the silicon wafer with hydrochloric acid/hydrogen peroxide, an interface layer made of SiO₂ is formed. After the interface layer is formed, at block 110, a HfO₂ film having a thickness of, e.g., about 2.5 nm is formed on the silicon wafer W as a first high-k insulating film by ALD. Then, at block 120, spike annealing is performed at a temperature of, e.g., about 700° C. Further, at block 130, a TiO₂ film having a thickness of, e.g., about 3 nm is formed as a second high-k insulating film by PVD. Then, an XRD analysis of the obtained film is performed, and the analysis result is provided in FIG. 9 by a solid line as an experimental example. Further, FIG. 9 also provides, as a comparative example, an XRD analysis result of a film obtained by performing heat-treatment at a temperature of, e.g., about 900° C. for about 10 minutes in block 120 without performing a subsequent process. This comparative example is indicated by a dashed line.

As can be seen from FIG. 9, in the film obtained by the method of the comparative example, a peak originated from a stable monoclinic crystal system (having a relative permittivity (∈) of about 16) is observed after the heat-treatment. Meanwhile, in case of the film obtained by the method of the experimental example, since the short-time crystallization heat-treatment (spike annealing) is performed after the HfO₂ film is formed, the TiO₂ film is formed thereafter, and then, a high-temperature heat-treatment is not performed after the TiO₂ film is formed, a peak originated from a semi-stable cubic crystal system (having a relative permittivity (∈) of about 29) is observed. This result may indicate that the HfO₂ crystal system having a high relative permittivity (for example, cubic crystal system) can be obtained by the semiconductor device manufacturing method according to the example embodiment, and, thus, an electrical characteristic of the obtained film can be improved.

### Third Example Embodiment

Now, an experiment for investigating the effect of the plasma process (block 115) and a thickness of a second high-k insulating film in the semiconductor device manufacturing method in accordance with the example embodiment will be explained.

First, at block 100, a surface of a silicon wafer is cleaned by, e.g., dilute hydrofluoric acid. Then, by cleaning the silicon wafer with hydrochloric acid/hydrogen peroxide, an interface layer made of SiO₂ is formed. After the interface layer is formed, at block 110, a HfO₂ film having a thickness of, e.g., about 2.5 nm is formed on the silicon wafer W as a first high-k insulating film by ALD. Then, a plasma process is performed on the HfO₂ film. At this time, in some examples, the plasma process is not performed. Thereafter, at block 120, spike annealing is performed at a temperature of, e.g., about 700° C. Further, at block 130, a TiO₂ film having a thickness in the range from, e.g., about 0 nm (0 nm indicates a case where a TiO₂ film is not formed) to about 5 nm is formed as a second high-k insulating film by PVD. Then, at block 140, a TiN having a thickness of, e.g., about 10 nm is formed as a gate electrode, and heat-treatment is performed at a low temperature of, e.g., about 400° C. for, e.g., about 10 minutes. As a result, a semiconductor device is manufactured.

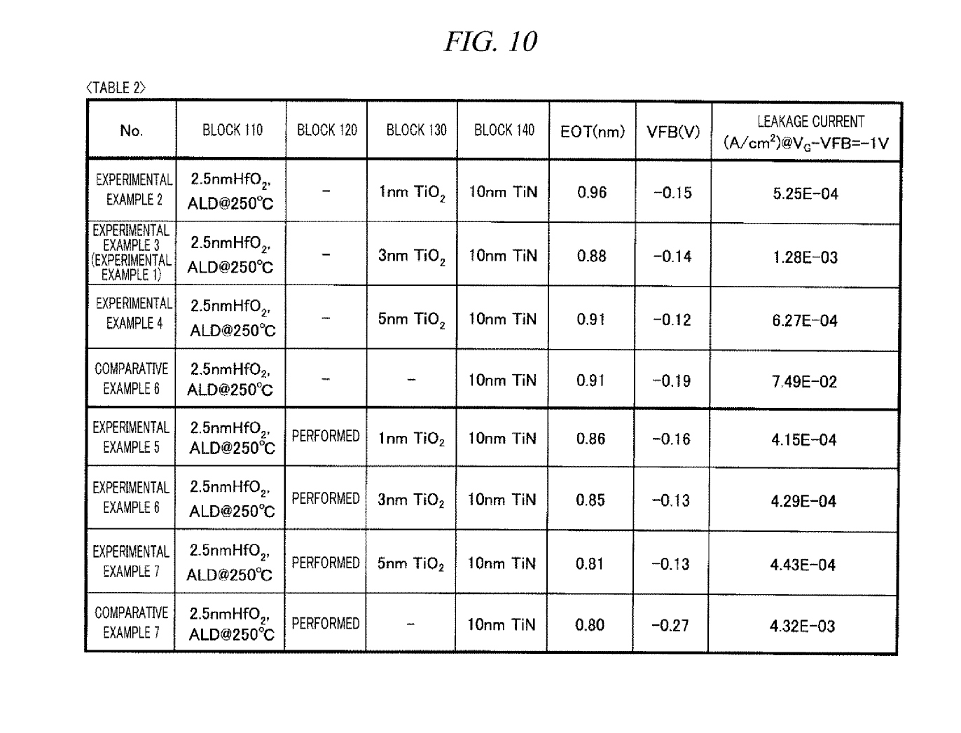

In the third example embodiment, detailed manufacturing conditions of experimental examples and the comparative examples are shown in Table 2 of FIG. 10.

Table 2 shows EOTs (nm) and leakage currents (A/cm²) of semiconductor devices obtained in the experimental examples and the comparative examples. Further, a flat band voltage (VFB; V) is also shown in Table 2.

As can be seen from Table 2, it is found that it is possible to reduce the EOT values and suppress the leakage current by performing the plasma process. It may be because as a result of performing the plasma process, a microstructure remaining after the formation of the HfO₂ film is removed and a cubic crystal system or a tetragonal crystal system having a high relative permittivity can be easily precipitated in the crystallization heat-treatment.

Further, as can be seen from Table 2, in the range of the third example embodiment, both the EOT and the leakage current have low dependency on the thickness of the second high-k insulating film. By forming (stacking) the second high-k insulating film of, e.g., about 5 nm or less, it is possible to reduce the EOT values and suppress the leakage current.

### Fourth Example Embodiment

Now, a case of forming a WO₃ film as a second high-k insulating film in the semiconductor device manufacturing method in accordance with the present example embodiment will be explained.

First, at block 100, a surface of a silicon wafer is cleaned by, e.g., dilute hydrofluoric acid. Then, by cleaning the silicon wafer with hydrochloric acid/hydrogen peroxide, an interface layer made of SiO₂ is formed. After the interface layer is formed, at block 110, a HfO₂ film having a thickness of, e.g., about 2.5 nm is formed on the silicon wafer W as a first high-k insulating film by ALD. Thereafter, at block 120, spike annealing is performed at a temperature of, e.g., about 700° C. Further, at block 130, a WO₃ film having a thickness in the range from, e.g., about 0.2 nm to about 5 nm is formed as a second high-k insulating film by PVD. Then, at block 140, a TiN having a thickness of, e.g., about 10 nm is formed as a gate electrode, and heat-treatment is performed at a low temperature of, e.g., about 400° C. for, e.g., about 10 minutes. As a result, a semiconductor device is manufactured.

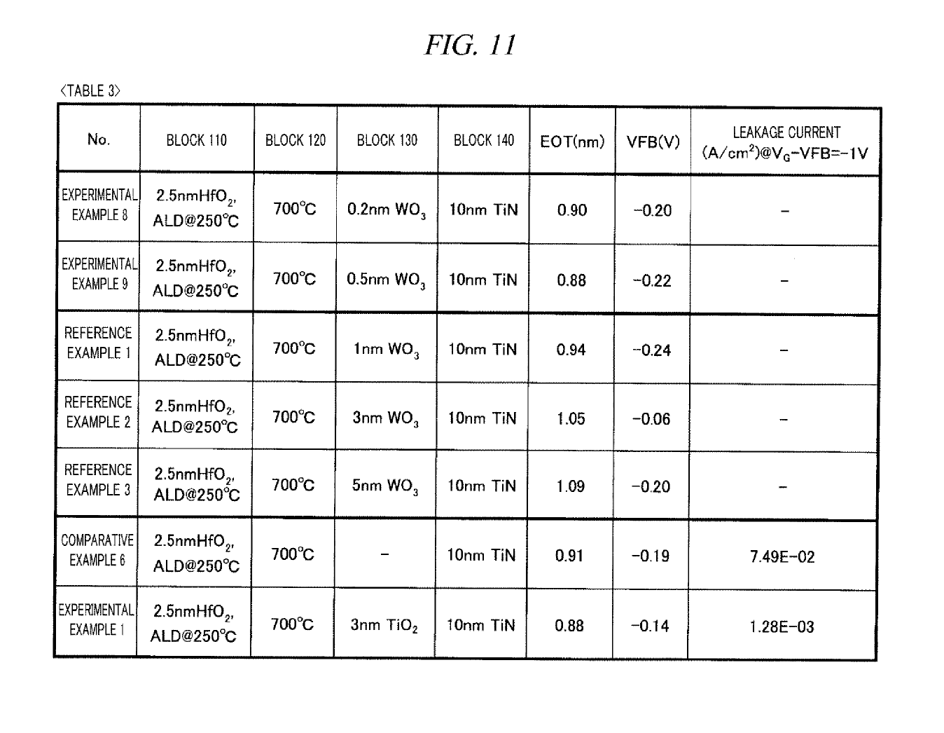

In the fourth example embodiment, detailed manufacturing conditions of experimental examples are shown in Table 3 of FIG. 11. Table 3 also shows the manufacturing conditions and the results of the experimental example 1 and a comparative example 5 in Table 1 for reference.

Table 3 shows EOTs (nm) of semiconductor devices obtained in the experimental examples and the comparative examples. Further, flat band voltages (VFB; V) are also shown in Table 3.

As can be seen from Table 3, in case of using the WO₃ film as the second high-k insulating film, by forming the WO₃ film in a thickness ranging from, e.g., about 0.2 nm to about 0.5 nm, it may be possible to reduce the EOT.

From the foregoing, it will be appreciated that various embodiments of the present disclosure have been described herein for purposes of illustration and are not intended to be limiting, and that various modifications may be made. By way of example, the method of forming the gate insulating film in accordance with the example embodiment may also be applicable to a method for forming a capacitive insulating film (capacitor capacitive film) of a capacitor. Further, in the above-described embodiment, the silicon wafer (silicon substrate) is used as a processing target object. However, other kinds of semiconductor substrates may also be used.

This international application claims priority to Japanese Patent Application No. 2011-195246, filed on Sep. 7, 2011, which application is hereby incorporated by reference in its entirety.

### EXPLANATION OF CODES

1, 2: Film forming apparatus
3: Plasma processing apparatus
4: Crystallizing apparatus
6,7: Load lock chamber
20: Controller
22: Storage unit
200: Substrate processing system
G: Gate valve
W: Semiconductor wafer

1. A semiconductor device manufacturing method comprising:
forming a first high-k insulating film on a processing target object;
performing a crystallization heat-treatment process on the first high-k insulating film at a temperature equal to or higher than about 650° C. for a time less than about 60 seconds; and
forming, on the first high-k insulating film, a second high-k insulating film containing a metal element having an ionic radius smaller than that of a metal element of the first high-k insulating film and having a relative permittivity higher than that of the first high-k insulating film.

2. The semiconductor device manufacturing method of claim 1, further comprising:
performing a plasma process on the first high-k insulating film before the performing of the crystallization heat-treatment process.

3. The semiconductor device manufacturing method of claim 1,
wherein the crystallization heat-treatment process is performed in a spike annealing device.

4. The semiconductor device manufacturing method of claim 1,
wherein the first high-k insulating film includes a hafnium oxide film, a zirconium oxide film, a zirconium hafnium oxide film or a stacked film of combinations thereof.

5. The semiconductor device manufacturing method of claim 1,
wherein the second high-k insulating film includes a titanium oxide film, a tungsten trioxide or titanate film.

6. The semiconductor device manufacturing method of claim 1,
wherein the second high-k insulating film has a thickness equal to or less than about 5 nm.

7. A substrate processing system comprising:
a first film forming apparatus configured to form a first high-k insulating film on a processing target object;
a crystallizing heat-treatment apparatus configured to perform a heat-treatment process on the first high-k insulating film at a temperature equal to or higher than about 650° C. for a time less than about 60 seconds; and
a second film forming apparatus configured to form, on the first high-k insulating film, a second high-k insulating film containing a metal element having an ionic radius smaller than that of a metal element of the first high-k insulating film and having a relative permittivity higher than that of the first high-k insulating film, after the completion of performing the crystallization heat-treatment in the crystallizing apparatus.

8. The substrate processing system of claim 7, further comprising:
a controller configured to control the first film forming apparatus, the crystallizing heat-treatment apparatus and the second film forming apparatus such that the first high-k insulating film is formed, the heat-treatment process is performed and the second high-k insulating film is formed in this sequence.

9. A substrate processing system comprising:
a first film forming apparatus configured to form a first high-k insulating film on a processing target object;
a plasma processing apparatus configured to perform a plasma process on the first high-k insulating film;
a crystallizing heat-treatment apparatus configured to perform a heat-treatment process on the first high-k insulating film at a temperature equal to or higher than about 650° C. for a time less than about 60 seconds; and
a second film forming apparatus configured to form, on the first high-k insulating film, a second high-k insulating film containing a metal element having an ionic radius smaller than that of a metal element of the first high-k insulating film and having a relative permittivity higher than that of the first high-k insulating film, after the completion of performing the crystallization heat-treatment in the crystallizing apparatus.

10. The substrate processing system of claim 9, further comprising:
a controller configured to control the first film forming apparatus, the plasma processing apparatus, the crystallizing heat-treatment apparatus and the second film forming apparatus such that the first high-k insulating film is formed, the plasma process is performed, the heat-treatment process is performed and the second high-k insulating film is formed in this sequence.
